(19) United States
(12) Patent Application Publication
(10) Pub. No.: US 2010/0108123 A1
(43) Pub. Date: May 6, 2010

(54) INTERCONNECTING REFLECTOR RIBBON FOR SOLAR CELL MODULES

(75) Inventors: Ingemar Åsberg, Charlottenberg (SE); Erik Sauar, Oslo (NO); Eckehard Hofmüller, Oslo (NO)

Correspondence Address: BIRCH STEWART KOLASCH & BIRCH, PO BOX 747, FALLS CHURCH, VA, 22040-0747, US

(73) Assignee: Renewable Energy Corporation ASA, Sandvika (NO)

(21) Appl. No.: 12/525,223

(22) PCT Filed: Jan. 30, 2008
(86) PCT No.: PCT/NO2008/000031

§ 371 Date: Sep. 2, 2009

Related U.S. Application Data
(60) Provisional application No. 60/887,353, filed on Jan. 31, 2007.

(51) Int. Cl. H01L 31/052

(52) U.S. Cl. 136/246

(57) ABSTRACT

A solar cell module comprises a light receiving structure with a substantially transparent front cover and a plurality of active elements placed behind the said front cover. At least one interconnector is situated between adjacent active elements, the interconnectors having a reflective structure facing towards said front cover.

### BACKGROUND OF THE INVENTION

The present invention regards generally to solar cell modules.

Usually, solar cells are electrically connected, and combined into “modules”, or solar panels. Solar panels have a sheet of glass on the front, and a resin encapsulation behind to keep the semiconductor wafers safe from the elements (rain, hail, etc) and give protection against corrosion. Solar cells are usually connected in series in modules, so that their voltages add. This interconnection is provided by a metallic interconnector attached on two adjacent solar cells.

In conventional flat-panel solar cell modules, the active elements, i.e. solar cells, account for the largest share of the costs due to expensive material and manufacturing process.

To cut the costs of a solar cell module it is thus desirable to reduce the density of the active elements within the module, while still capturing mostly the same amount of light incident on the solar module. Thus the incident light on areas not covered by an active element has to be redirected towards adjacent active elements.

The patent WO001999056317 shows a solution for a solar cell module comprising a structure to redirect incident sun light from areas not covered by active elements towards adjacent active elements. Thus a laminated plastic film with embossed V-grooves and additional metallic reflective coating on the grooves is placed between adjacent active elements into a solar cell module in such a way that the reflective grooves are facing towards the covering front glass sheet. The reflective grooves have a certain angle so that incident light reflected by the grooves will hit the front surface of the covering glass under an angle bigger than the critical angle which leads to an internal reflection and than travel further towards an active element. In this invention the reflective film is placed into the gap between two adjacent cells which may interfere with the cell interconnection. Also the metallic coating of the reflective film may affect the insulation between the solar cells and the strings of interconnected solar cells.

### SUMMARY OF THE INVENTION

The object of the present invention is made to simplify the embodiment of a solar cell module comprising solar cells, interconnectors and reflective elements to redirect incident light from areas not covered by solar cells towards the solar cells. The object of the invention is further fully or partly to solve the above described problems. In the present invention the functions of electrically interconnecting two adjacent cells and redirecting incident sun light towards these cells are combined into one element. Additionally this element is in one embodiment capable of releasing mechanical stress between the solar cells induced by thermal expansion under different climatic conditions.

The objects of the invention is solved by means of the features in the patent claims. According to one embodiment of the invention, a solar cell module comprises

a light receiving structure having a sufficiently transparent front cover and
a plurality of active elements placed behind the said front cover and
a plurality of interconnectors comprising at least one electric conductive layer and each interconnecting minimum two adjacent said active elements
wherein said interconnectors having a reflective structure facing towards said front cover to direct incident light to the front surface of said front cover and reflect internally further onto said active elements.

According to another embodiment of the invention, the interconnectors cover 30%-100% of the area between the active elements.

According to still another embodiment the interconnectors have spring elements to provide stress release between said two interconnected adjacent active elements.

In one embodiment of the invention the interconnectors are V-groove shaped and reflective coated to provide at the same time said reflective structure and stress release.

In one embodiment the interconnectors are embossed with V-grooves smaller than the thickness of said interconnectors and reflective coated to provide said reflective structure.

In another embodiment an additional polymeric film with embossed V-grooves and a reflective coating is attached to said interconnectors to provide said reflective structure. The polymeric film may be a ready structured and reflective coated tape.

The polymeric film may be made by a liquid or soft resin coated, embossed, cured and reflective coated direct onto the said interconnector.

In one embodiment the angle of the said V-grooves are such that light incident on the said V-grooves is reflected back into the said transparent front cover with an angle larger than the critical angle.

The vertex angle of the said V-grooves is for example in the range of 110°-130°.

The reflective coating may be a Ag, Al, Au or reflective polymer layer.

The reflective coating may be protected from corrosion by an additional transparent protective coating.

The active elements are in one embodiment back contacted solar cells.

In one embodiment the active elements are back- and front contacted solar cell.

The interconnector may be made of a metal or a metal alloy with good electric conductivity such as Cu, Al, Ag or other.

The interconnectors may be connected to the said active elements by soldering.

In one embodiment at least the contact areas of the said interconnectors are coated by tin or one of its alloys to provide better solderability.

In one embodiment, the solar cells or solar cell areas with additional irradiance from the reflective structure have a higher contact finger density.

### BRIEF DESCRIPTION OF THE DRAWINGS

The present invention may be more fully understood from the detailed description accompanied with these drawings:

FIG. 1: A complete solar cell module comprising solar cells and interconnectors according to the present invention.

FIG. 2: Front and back view of two adjacent solar cells interconnected by an interconnector according to the present invention.

FIG. 3: A variety of interconnector designs according to the present invention.

FIG. 4: Cross section view of cell interconnection from back to back and from back to front.

FIG. 5: This figure illustrates a detailed cross section view of three different methods to provide the desired structure on the interconnector.

FIG. 6: Shows the principles of the reflective structure on the interconnectors.

### DETAILED DESCRIPTION OF THE INVENTION

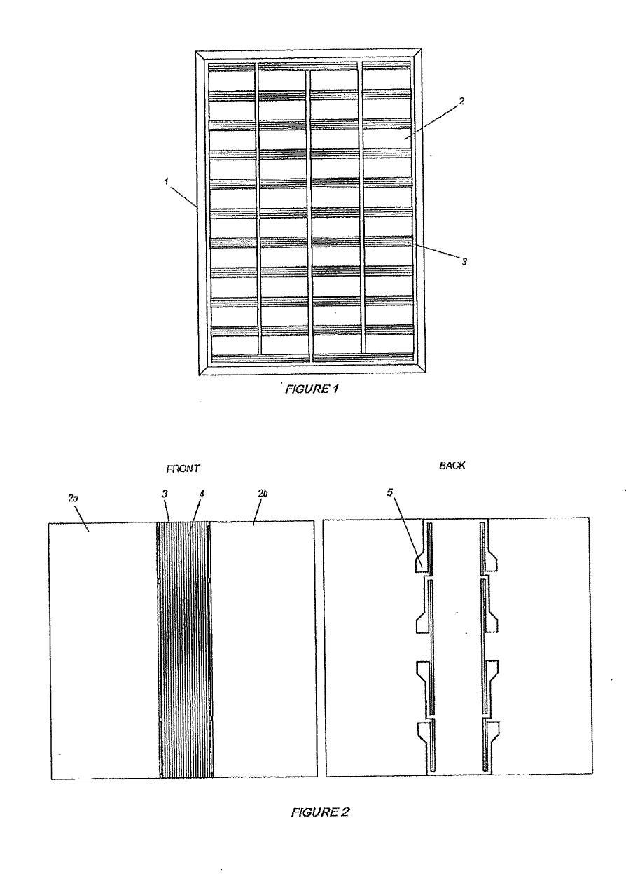

The FIG. 1 shows a complete solar cell module 1 with a number of in series interconnected solar cells 2 whereas the solar cells 2 are interconnected by interconnectors 3. One or more strings of alternating solar cells 2 and interconnectors 3 are interconnected and transparently encapsulated behind a transparent front cover. This front cover may be a sheet of glass whereas EVA may be used as the transparent encapsulation material.

With reference to FIG. 2 which shows a detail of a interconnection as shown in FIG. 1, two adjacent solar cells 2a and 2b are interconnected by an interconnector 3. The front surface, i.e. light receiving surface of the interconnector 3 is substantially completely covered by a reflective structure 4. The interconnector 3 comprises on its longitudinal edges connection elements 5 connected to an elongated bar 6. These are to be connected to corresponding connection islands on the solar cells by means of soldering or any other suitable connection means. The interconnector 3 might be made of a material with good electrical conductivity such as copper.

The connection elements may move slightly with respect to the main body of the interconnector 3 and with respect to other connection elements connected to the interconnector 3. This interconnector arrangement is preferably flexible to ensure sufficient stiffness of the interconnector while allowing some relative movement between the different parts in a solar cell assembly. This design results into a stress releasing spring structure of the interconnector 3 to compensate displacements of the interconnected solar cells 2a and 2b caused by the thermal expansion under different operating temperatures. The bars 6 might be designed meandering to provide also a better stress release between the connection elements 5 and the main body of the interconnector 3.

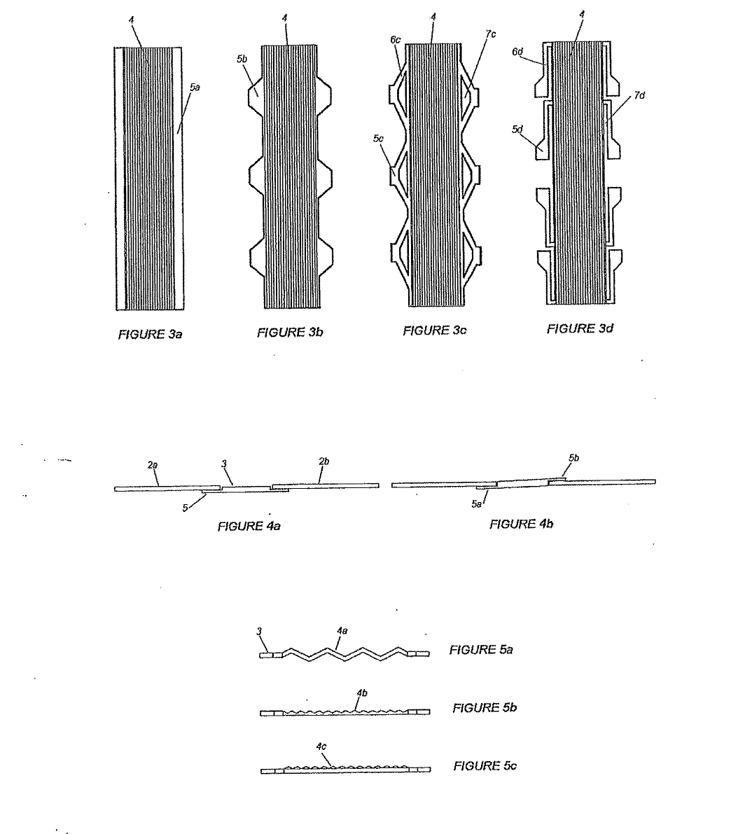

The FIGS. 3a to 3d show a variety of exemplary interconnector designs. FIG. 3a demonstrates a very basic design of the interconnector with the reflective surface 4 in the middle area and both longitudinal edges as the connection elements 5a to connect to the solar cells. Depending on the contact design of the solar cells single connection elements 5b may also be arranged as drawn out of the interconnector as shown in FIG. 3b. Designs resulting into a stress releasing spring structure of the interconnector to compensate displacements of the interconnected solar cells caused by thermal expansion under different operating temperatures are demonstrated in FIG. 3c and FIG. 3d. With reference to FIG. 3c an opening 7c is made into the interconnector next to each connection element 5c so that each connection element 5c is linked by only thin bars 6c to the interconnector providing a higher elasticity.

In the design shown in FIG. 3d, which corresponds to the embodiment in FIG. 2, connection elements 5d are drawn out from the edges of the interconnector and each linked by a longer bar 6d forming a thin gap 7d between the main body of the interconnector and the connection elements 5d. The bars 6d might be designed meandering to provide a better stress release also between the connection elements 5d and the main body of the interconnector.

Depending on the type of solar cells used in the solar cell module 1 there are two methods to apply the interconnection. As illustrated in FIG. 4a the interconnector 3 can be applied to interconnect the solar cell 2a and 2b by connecting the connection elements 5 on both solar cells on the back surface. In FIG. 4b the connection elements 5a of the interconnector 3 are connected to the back surface of the solar cell 2a and the connection elements 5b of the interconnector 3 to the front surface of the adjacent solar cell 2b. Preferably connection of the connection elements 5 of the interconnectors 3 to the corresponding metalized connection islands on the solar cells is done by soldering. Thus a tin coating of at least of the connection elements 5 is appropriate but also the complete interconnector 3 might be tin coated.

FIG. 5a demonstrates a first method to provide the desired shape for the reflective structure 4a on the interconnector 3. A V-grooved shape is realized by punching the body of the interconnector 3 so that in a cross section view the body of the interconnector 3 appears in a zigzag shape with its amplitude higher than the thickness of the interconnector 3 but not higher than the thickness of the solar cell and the encapsulation. To improve the reflectivity of the reflective structure 4a an additional reflective coating might be applied.

A second method to shape the reflective structure 4b on the interconnector 3 is shown in FIG. 5b. Embossing the body of the interconnector 3 provides the V-grooves for the reflective structure 4b. Thereby the amplitude of the grooves has to be smaller than the thickness of the interconnector 3 so that only the front surface of the interconnector 3 is structured while the back surface remains plain. To improve the reflectivity of the reflective structure 4a an additional reflective coating might be applied.

In FIG. 5c a third method to provide the desired shape is illustrated. A layer 4c of an additional material preferably a polymer is attached on the main body of the interconnector 3. Thereby the additional layer 4c might be embossed to provide the desired shape before or after it is attached to the interconnector 3. To provide the necessary reflectivity an additional reflective coating is deposited onto the layer 4c.

The desired shape which might be provided by one of the above mentioned methods are V-grooves with an angle such that incident light on this V-grooves is reflected back into the front cover with an angle bigger than the critical angle so that it will be internally reflected on the front surface of the front cover. It has been found out that an angle in the range of 110°-130° is a favorable design for the V-grooves.

The additional coating to improve the reflectivity of the reflective structure 4 is preferably an Ag layer but might be also Al, Au, reflective polymer or other material. To prevent a reflectivity drop of this reflective coating caused by corrosion especially before the interconnectors 3 are encapsulated within a solar cell module a transparent protective coating might be applied on top of the reflective coating.

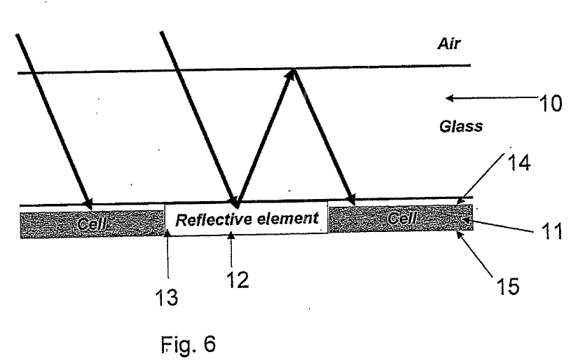

FIG. 6 illustrates the principle of reflective structure on the interconnectors. The transparent front plate 10 overlies a plurality of solar cells 11 which are arranged spaced from each other, providing areas 13 with no solar cells. The solar cells 11 are electrically interconnected by interconnectors with reflective structure 12 and have a front side 14 and a back side 15. The reflective structure 12 is arranged in the gap 13 between the solar cells. Light incident on the area 13 without any solar cell is reflected off the reflective structure 12 and back into the transparent front plate 10, and reflected again off the interface between the front plate 10 and air by total internal reflection (TIR) towards a solar cell 11.

1-19. (canceled)

20. A solar cell module comprising
a light receiving structure having a substantially transparent front cover, and
a plurality of active elements placed behind the said front cover, and
at least one interconnector situated between adjacent active elements,
wherein the interconnectors have a reflective structure facing towards said front cover and the interconnectors comprise spring elements to provide stress release between interconnected adjacent active elements.

21. The solar cell module of claim 20, wherein the interconnector(s) comprise at least one electric conductive layer.

22. The solar cell module of claim 20,
wherein said interconnectors are covering 30%-100% of the area between the active elements.

23. The solar cell module of claim 20,
wherein said interconnectors are V-groove shaped and reflective coated to provide at the same time said reflective structure and stress release.

24. The solar cell module of claim 20,
wherein said interconnectors are embossed with V-grooves smaller than the thickness of said interconnectors and reflective coated to provide said reflective structure.

25. The solar cell module of claim 20,
wherein an additional polymeric film with embossed V-grooves and a reflective coating is attached to said interconnectors to provide said reflective structure.

26. The solar cell module of claim 25,
wherein the said polymeric film is a ready structured and reflective coated tape.

27. The solar cell module of claim 25,
wherein the said polymeric film is made by a liquid or soft resin coated, embossed, cured and reflective coated direct onto the said interconnector.

28. The solar cell module of claim 23,
wherein the angle of the said V-grooves are such that light incident on the said V-grooves is reflected back into the said transparent front cover with an angle larger than the critical angle.

29. The solar cell module of claim 28,
wherein the vertex angle of the said V-grooves is in the range of 110°-130°.

30. The solar cell module of claim 23,
wherein the said reflective coating is a Ag, Al, Au or reflective polymer layer.

31. The solar cell module of claim 30,
wherein the said reflective coating is protected from corrosion by an additional transparent protective coating.

32. The solar cell module of claim 20,
wherein the said active elements are back contacted solar cells.

33. The solar cell module of claim 20,
wherein the said active elements are back- and front contacted solar cell.

34. The solar cell module of claim 20,
wherein the said interconnector is made of a metal or a metal alloy with good electric conductivity such as Cu, Al, Ag or other.

35. The solar cell module of claim 20,
wherein the said interconnectors are connected to the said active elements by soldering.

36. The solar cell module of claim 34,
wherein at least the contact areas of the said interconnectors are coated by tin or one of its alloys to provide better solderability.

37. The solar cell module of claim 20,
wherein the solar cells or solar cell areas with additional irradiance from the reflective structure have a higher contact finger density.

38. The solar cell module of claim 24,
wherein the angle of the said V-grooves are such that light incident on the said V-grooves is reflected back into the said transparent front cover with an angle larger than the critical angle.

39. The solar cell module of claim 25,
wherein the angle of the said V-grooves are such that light incident on the said V-grooves is reflected back into the said transparent front cover with an angle larger than the critical angle.
